(19) United States
(12) Patent Application Publication
(10) Pub. No.: US 2021/0189551 A1
(43) Pub. Date: Jun. 24, 2021

(54) VACUUM COATING DEVICE FOR FLEXIBLE SUBSTRATE

(71) Applicant: MIASOLÉ EQUIPMENT INTEGRATION (FUJIAN) CO., LTD., FUJIAN (CN)

(72) Inventors: HONGXIA SUN, FUJIAN (CN); YANG ZHOU, FUJIAN (CN); HU JIANG, FUJIAN (CN); CHAO HU, FUJIAN (CN); YI SHU, FUJIAN (CN); PENGJIAN ZHU, FUJIAN (CN); FAN CHEN, FUJIAN (CN); DENG PAN, FUJIAN (CN); WEI LONG, FUJIAN (CN)

(21) Appl. No.: 16/068,519

(22) PCT Filed: Jun. 15, 2018
(86) PCT No.: PCT/CN2018/091570

§ 371 Date: Jul. 6, 2018

(30) Foreign Application Priority Data
Dec. 6, 2017 (CN) 201721681092.X

(51) Int. Cl. C23C 14/56; F28F 5/02

(52) U.S. Cl. CPC C23C 14/56; F28F 5/02

(57) ABSTRACT

A vacuum coating device for a flexible substrate is provided, including a vacuum coating chamber and a transition chamber which are connected to each other. The vacuum coating chamber and the transition chamber communicate with each other through a slit. The vacuum coating device further includes a cooling roller, which is fixed in the transition chamber through a tension adjusting component. The cooling roller includes a roller body and a shaft, the roller body is fixedly installed on the shaft, and the roller body and the shaft are coaxial. Multiple heat dissipation passages are provided in the roller body along an axial direction of the roller body. Good cooling function is achieved and the flexible substrate is prevented from generating winkles.

### CROSS-REFERENCE TO RELATED APPLICATIONS

The present application is the US national phase of PCT Application No. PCT/CN2018/091570 filed on Jun. 15, 2018, which claims a priority to Chinese Patent Application No. 201721681092.X filed on Dec. 6, 2017, the disclosures of which are incorporated in its entirety by reference herein.

### TECHNICAL FIELD

The present disclosure relates to a vacuum coating device, and more particularly, to a vacuum coating device for a flexible substrate.

### BACKGROUND

The vacuum coating device is widely used in the photovoltaic field. Specifically, for coating a flexible substrate, the winding-type coating equipment based on continuous coating and magnetron sputtering has advantages such as high coating efficiency, compact structure and occupying small room.

The vacuum coating device mainly includes a feed chamber, a vacuum coating chamber, a transition chamber and a discharge chamber. A water cooler is provided in the transition chamber. The water cooler is connected to a roller and may cool the flexible substrate through the roller. The flexible substrate, out of the vacuum coating chamber and entering the transition chamber, may turn uneven after being cooled through the roller due to relatively large temperature change, hence, the yield of flexible substrates is adversely affected. Furthermore, the roller in the transition chamber is an active roller which is belt driven. The roller may somehow pull the flexible substrate, hence, the surface tension of the flexible substrate may be affected and the flexible surface may have additional risk of wrinkling.

### SUMMARY

The present disclosure provides a vacuum coating device for a flexible substrate, including a vacuum coating chamber and a transition chamber which are connected to each other, the vacuum coating chamber and the transition chamber communicating with each other through a slit. The vacuum coating device further includes a cooling roller fixed in the transition chamber through a tension adjusting component. The cooling roller includes a roller body and a shaft, the roller body is fixedly installed on the shaft, and the roller body and the shaft are coaxial. Multiple heat dissipation passages are provided in the roller body along an axial direction of the roller body.

Optionally, the cooling roller rotates passively.

Optionally, the roller body is provided with an installation hole, the shaft penetrates through the installation hole, a diameter of the shaft is smaller than a diameter of the installation hole, and the shaft is fixedly connected to an internal surface of the installation hole through a connection plate.

Optionally, the connection plate has an integral spiral structure.

Optionally, there are at least two connection plates and adjacent connection plates are arranged in a staggered manner.

Optionally, each heat dissipation passage is provided with multiple through-holes in communication with the installation hole.

Optionally, the multiple heat dissipation passages are spaced with a same interval along a circumferential direction of an end surface of the roller body.

Optionally, the tension adjusting component is provided at each end of the cooling roller, the two tension adjusting components are of the same structure and arranged oppositely. Each tension adjusting component includes a shaft installation base, a base plate and an exterior plate, the base plate is arranged on an internal surface of the transition chamber, the exterior plate is arranged on an exterior surface of the transition chamber and is fixedly connected to the base plate via a screw. Two opposite pressing blocks are arranged on a side of the base plate facing the cooling roller, the shaft installation base is arranged between the two pressing blocks and is slidably connected with the pressing blocks. A second base is further provided on the base plate, the second base is arranged along a sliding direction of the shaft installation base, an adjusting screw rod is arranged on the second base and one end of the adjusting screw rod is in threaded connection with the shaft installation base, and the shaft is rotatably installed on the shaft installation base.

Optionally, the pressing blocks each have an L-shaped structure.

Optionally, the shaft installation base is provided with a bearing installation hole, a bearing is installed in the bearing installation hole, a circular groove is provided at each end of the shaft, and one U-shaped snap ring is installed in each circular groove, where the U-shaped snap ring is configured to limit a degree of freedom of the bearing in an axial direction of the bearing.

Optionally, a third base is provided at a lateral side of each pressing block, a waist-type hole is arranged at a lateral side of the shaft installation base facing the third base, a guide screw is arranged on the third base, and the guide screw penetrates through the shaft installation base and slidably engages with the waist-type hole.

Optionally, the base plate is provided with a second waist-type hole which extends along the sliding direction of the shaft installation base.

Optionally, the vacuum coating device for flexible substrate further includes a shaft sleeve having a split-type structure, where the shaft sleeve is sleeved onto an end portion of the shaft and configured to prevent the cooling roller from vibrating in an axial direction of the cooling roller.

Optionally, a position of the shaft sleeve is limited by a guide ring.

### BRIEF DESCRIPTION OF THE DRAWINGS

FIG. 1 is a front view of the present disclosure;

FIG. 2 is an bottom view of the present disclosure;

FIG. 3 is an axonometric drawing of a cooling roller;

FIG. 4 is a sectional view of a roller body;

FIG. 5 is a schematic structural diagram of a shaft, a connection plate, a bearing and a U-shaped snap ring;

FIG. 6 is axonometric drawing of a part of a cooling roller when being sectioned;

FIG. 7 is an exploded view of a tension adjusting component; and

FIG. 8 is an exploded view of a tension adjusting component from another perspective.

Numerical references as explained as follows:
1—vacuum coating chamber, 2—transition chamber, 3—cooling roller, 4—tension adjusting component, 5—roller body, 6—shaft, 7—heat dissipation passage, 8—installation hole, 9—connection plate, 10—bearing, 11—circular groove, 12—U-shaped snap ring. 13—through-hole, 14—shaft installation base, 15—base plate, 16—exterior plate, 17—pressing block, 18—second base, 19—adjusting screw rod, 20—bearing installation hole, 21—third base, 22—waist-type hole, 23—guide screw, 24—second waist-type hole, 25—sealing ring, 26—shaft sleeve, 27—guide ring.

### DETAILED DESCRIPTION

Embodiments of the present disclosure are detailed hereinafter. Examples according to the embodiments are shown in the drawings. The same or similar numerical references throughout the disclosure represent the same or similar components or components having same or similar functions. The following embodiments described in conjunction with the drawings are exemplary, which are used to explain the present disclosure rather than to limit the present disclosure.

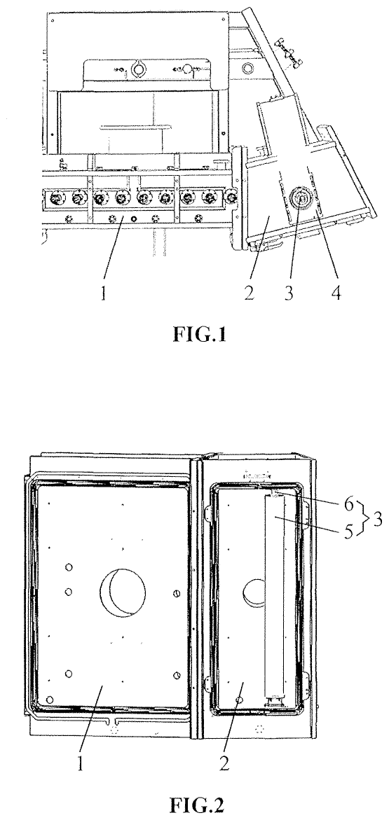

A vacuum coating device for a flexible substrate is provided according to an embodiment of the present disclosure. As shown in FIG. 1 to FIG. 3, the vacuum coating device includes a vacuum coating chamber 1 and a transition chamber 2 which are connected to each other. Usually, a feed chamber is provided before the vacuum coating chamber 1 and a discharge chamber is provided after the transition chamber 2, which are not shown in the drawings. Adjacent chambers communicate with each other through a slit. A cooling roller 3 is provided in the transition chamber 2. The cooling roller 3 is fixed in the transition chamber 2 through a tension adjusting component 4. The cooling roller 3 includes a roller body 4 and a shaft 6. The roller body 5 is fixedly installed on the shaft 6. The roller body 5 and the shaft 6 are coaxial. Several heat dissipation passages 7 are provided in the roller body 5 along an axial direction of the roller body 5. Optionally, the heat dissipation passages 7 are spaced with a same interval along a circumferential direction of an end surface of the roller body 5.

During operation, after being coated in the vacuum coating chamber 1, a flexible substrate enters the transition chamber 2 through the slit. As the flexible substrate moves, the cooling roller 3 rotates accordingly and heat is transferred from the flexible substrate to the cooling roller 3. As the cooling roller rotates, the heat is dissipated into air through the heat dissipation passages 7, hence, the flexible substrate is cooled down slowly and may not generate any wrinkle due to rapid cooling. In addition, the cooling roller 3 rotates passively and may not affect the tension of the flexible substrate. Hence, the winkling ratio is decreased. In the present disclosure, a conventional winkling ration of 24.5% can be significantly reduced to 2.7%.

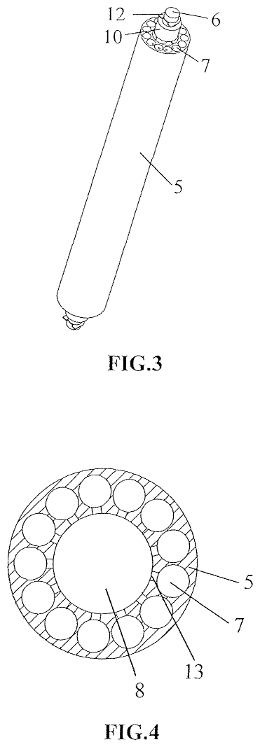

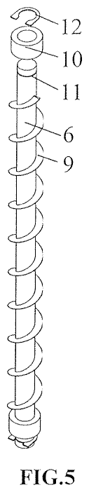

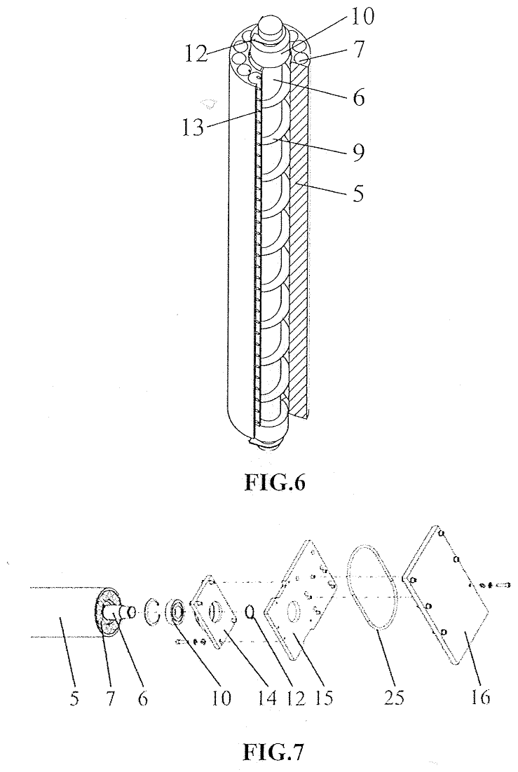

Since no auxiliary cooling device is provided in the present disclosure, the cooling roller 3 needs to be ensured with good cooling ability. An implementation of the cooling roller 3 is provided according to an embodiment of the present disclosure. As shown in FIG. 3 to FIG. 6, the roller body 5 is provided with an installation hole 8, the shaft 6 penetrates through the installation hole 8, and the diameter of the shaft 6 is smaller than the diameter of the installation hole 8. The shaft 6 is fixedly connected to an internal surface of the installation hole 8 through a connection plate 9. A sealing ring 25 is further provided between the shaft 6 and the internal surface of the installation hole 8, to prevent entrance of dust and water at a position where the sealing ring 25 connects the internal surface of the installation hole 8. The connection plate 9 may speed up flow of the air. The connection plate 9 may have an integral structure or a split-type structure. For the integral structure, the connection plate 9 is spiral. For the split-type structure, there are at least two connection plates 9, adjacent connection plates 9 need to be arranged in a staggered manner and each connection plate 9 and the axis of the shaft 6 form an angle. Each heat dissipation passage 7 is provided with several through-holes 13 in communication with the installation hole 8. Heat accumulated in the heat dissipation passages 7 may enter the installation hole 8 through the through-holes 13 and then be discharged out of the roller body 5 through the installation hole 8. Such structure may enhance a cooling effect of the present disclosure.

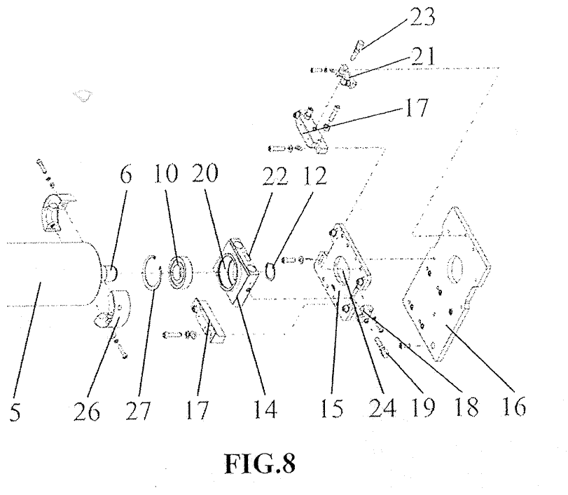

Since the cooling roller 3 rotates passively in the present disclosure, the cooling roller 3 needs to be adjusted to an appropriate position to meet basic requirements for tension. Tension adjusting components 4 are provided at both ends of the cooling roller 3. The two tension adjusting components 4 are of the same structure and arranged oppositely. As shown in FIG. 7 and FIG. 8, the tension adjusting component 4 includes a shaft installation base 14, a base plate 15 and an exterior plate 16. The base plate 15 is arranged on an internal surface of the transition chamber 2, the exterior plate 16 is arranged on an exterior surface of the transition chamber 2 and is fixedly connected to the base plate 15 via a screw. Two opposite pressing blocks 17 are arranged on a side of the base plate 15 facing the cooling roller 3. The shaft installation base 14 is arranged between the two pressing blocks 17 and is slidably connected with the pressing blocks 17. Optionally, the block 17 has an L shape, thereby well limiting the degree of freedom of the shaft installation base 14 in the axial direction of the shaft 6. A second base 18 is further provided on the base plate 15. The second base 18 is arranged along a sliding direction of the shaft installation base 14. An adjusting screw rod 19 is arranged on the second base 18 and one end of the adjusting screw rod 19 is in threaded connection with the shaft installation base 14. The shaft 6 is rotatably installed on the shaft installation base 14.

The cooling roller 3 may be adjusted as follows. By rotating the adjusting screw rod 19, here the adjusting screw rod 19 rotates on the second base 18 and may not move with respect to the second base 18, the shaft installation base 14 which is in threaded connection with the adjusting screw rod 19 may slide between the two tension adjusting components 4 as the adjusting screw rod 19 rotates, to change a position of the cooling roller 3, thereby adjusting the tension.

To enable the cooling roller 3 to rotate smoothly on the tension adjusting component 4, Optionally, the shaft installation base 14 is provided with a bearing installation hole 20, a bearing 10 is installed in the bearing installation hole 20, a circular groove 11 is provided at each end of the shaft 6, one U-shaped snap ring 12 is installed in each circular groove 11, where the U-shaped snap ring 12 is used to limit a degree of freedom of the bearing 10 in an axial direction. A shaft sleeve 26 may be further provided to prevent the cooling roller 3 from vibrating in the axial direction. Optionally, the shaft sleeve 26 has a split-type structure for easy installment. A position of the shaft sleeve 26 is limited by a guide ring 27. The base plate 15 is provided with a second waist-type hole 24 which extends along the sliding direction of the shaft installation base 14. The arrangement of the second waist-type hole 24 may prevent the cooling roller 3 from directly contacting the base plate 15 in case of vibrating in the axial direction. With the arrangement of the second waist-type hole 24, the cooling roller may not abut the base plate 15 even if the cooling roller vibrates in the axial direction.

A third base 21 is provided at a lateral side of each block 17. A waist-type hole 22 is arranged at a lateral side of the shaft installation base 14 facing the third base 21. A guide screw 23 is arranged on the third base 21. The guide screw 23 penetrates through the shaft installation base 14 and slidably engages with the waist-type hole 22. The arrangement of the guide screw 23 and the waist-type hole 22 may achieve functions of guiding and position limiting in the axial direction.

The embodiment provides a vacuum coating device for a flexible substrate to solve conventional technical problem. The vacuum coating device has good cooling function and can prevent the flexible substrate from generating winkles.

Compared with the conventional art, the embodiment does not need a cooling device and a driving device for the cooling roller, the roller body of the cooling roller is provided with multiple heat dissipation passages along its axial direction, when the cooling roller rotates, heat from the flexible substrate is dissipated into air through the heat dissipation passages. Such heat dissipation way is relatively gentle and may not cause sudden decreasing of temperature, thereby preventing generating winkles on the flexible substrate. In addition, the cooling roller passively rotates as driven by the flexible substrate, rather than actively rotates in the conventional art, hence, tension of the flexible substrate may not be affected, the tension can be maintained and the risk of generating winkles on the flexible substrate is further alleviated.

The constructions, features and functional effects of the present disclosure are detailed in the embodiments in conjunction with the drawings. The above-described embodiments are merely preferred embodiments of the present disclosure. The scope of the present disclosure is not limited to those shown by the drawings. Any change made based on the principle of the present disclosure or modified equivalent embodiments without departing from the spirit of the specification and drawings shall fall within the protection scope of the present disclosure.

What is claimed is:

1. A vacuum coating device for a flexible substrate, comprising a vacuum coating chamber and a transition chamber which are connected to each other, the vacuum coating chamber and the transition chamber communicating with each other through a slit;
wherein the vacuum coating device further comprises a cooling roller fixed in the transition chamber through a tension adjusting component;
wherein the cooling roller comprises a roller body and a shaft, the roller body is fixedly installed on the shaft, and the roller body and the shaft are coaxial; and
wherein a plurality of heat dissipation passages are provided in the roller body along an axial direction of the roller body.

2. The vacuum coating device according to claim 1, wherein the cooling roller rotates passively.

3. The vacuum coating device according to claim 1, wherein the roller body is provided with an installation hole, the shaft penetrates through the installation hole, a diameter of the shaft is smaller than a diameter of the installation hole, and the shaft is fixedly connected to an internal surface of the installation hole through a connection plate.

4. The vacuum coating device according to claim 3, wherein the connection plate has an integral spiral structure.

5. The vacuum coating device according to claim 3, wherein there are at least two connection plates and adjacent connection plates are arranged in a staggered manner.

6. The vacuum coating device according to claim 3, wherein each heat dissipation passage is provided with a plurality of through-holes in communication with the installation hole.

7. The vacuum coating device according to claim 1, wherein the plurality of heat dissipation passages is spaced with a same interval along a circumferential direction of an end surface of the roller body.

8. The vacuum coating device according to claim 2, wherein the tension adjusting component is provided at both ends of the cooling roller, the two tension adjusting components are of the same structure and arranged oppositely;
each tension adjusting components comprises a shaft installation base, a base plate and an exterior plate, the base plate is arranged on an internal surface of the transition chamber, the exterior plate is arranged on an exterior surface of the transition chamber and is fixedly connected to the base plate via a screw;
two opposite pressing blocks are arranged on a side of the base plate facing the cooling roller, the shaft installation base is arranged between the two pressing blocks and is slidably connected with the pressing blocks;
a second base is further provided on the base plate, the second base is arranged in a sliding direction of the shaft installation base, an adjusting screw rod is arranged on the second base and one end of the adjusting screw rod is in threaded connection with the shaft installation base, and the shaft is rotatably installed on the shaft installation base.

9. The vacuum coating device according to claim 8, wherein the pressing blocks each have an L-shaped structure.

10. The vacuum coating device according to claim 8, wherein the shaft installation base is provided with a bearing installation hole, a bearing is installed into the bearing installation hole, a circular groove is provided at each end of the shaft, and one U-shaped snap ring is installed in each circular groove, wherein the U-shaped snap ring is configured to limit a degree of freedom of the bearing in an axial direction of the bearing.

11. The vacuum coating device according to claim 8, wherein a third base is provided at a lateral side of each pressing block, a waist-type hole is arranged at a lateral side of the shaft installation base facing the third base, a guide screw is arranged on the third base, and the guide screw penetrates through the shaft installation base and slidably engages with the waist-type hole.

12. The vacuum coating device according to claim 8, wherein the base plate is provided with a second waist-type hole which extends along the sliding direction of the shaft installation base.

13. The vacuum coating device according to claim 8, further comprising a shaft sleeve having a split-type structure, wherein the shaft sleeve is sleeved onto an end portion of the shaft and configured to prevent the cooling roller from vibrating in an axial direction of the cooling roller.

14. The vacuum coating device according to claim 13, wherein a position of the shaft sleeve is limited by a guide ring.

15. The vacuum coating device according to claim 2, wherein the roller body is provided with an installation hole, the shaft penetrates through the installation hole, a diameter of the shaft is smaller than a diameter of the installation hole, and the shaft is fixedly connected to an internal surface of the installation hole through a connection plate.

16. The vacuum coating device according to claim 15, wherein the connection plate has an integral spiral structure.

17. The vacuum coating device according to claim 15, wherein there are at least two connection plates and adjacent connection plates are arranged in a staggered manner.

18. The vacuum coating device according to claim 15, wherein each heat dissipation passage is provided with a plurality of through-holes in communication with the installation hole.
